(19) United States
(12) Patent Application Publication
(10) Pub. No.: US 2014/0102510 A1
(43) Pub. Date: Apr. 17, 2014

(54) CONCENTRATING SOLAR ENERGY COLLECTOR

(71) Applicant: Cogenra Solar, Inc., Mountain View, CA (US)

(72) Inventors: Jason Christopher KALUS, San Francisco, CA (US); Adam Thomas CLAVELLE, San Francisco, CA (US); Nathan BECKETT, San Leandro, CA (US); Ratson MORAD, Palo Alto, CA (US); Gilad ALMOGY, Palo Alto, CA (US)

(73) Assignee: COGENRA SOLAR, Inc., Mountain View, CA (US)

(21) Appl. No.: 13/651,246

(22) Filed: Oct. 12, 2012

(51) Int. Cl. G02B 5/10; B32B 37/14; B32B 37/12; H01L 31/052; H01L 31/18

(52) U.S. Cl. 136/246; 29/890.033; 156/60; 359/853

(57) ABSTRACT

Systems, methods, and apparatus by which solar energy is efficiently collected to provide heat, electricity, or a combination of heat and electricity include a solar energy collector having a receiver, a first reflector and a second reflector arranged end-to-end such that an edge of the first reflector overlaps an edge of the second receiver; and a support structure that accommodates movement of the receiver, rotation of the reflectors, or rotation of the receiver and the reflectors about an axis parallel to a long axis of the receiver. The support structure has reflector supports oriented transverse to the rotation axis and reflectors are securable to the reflector support.

### BACKGROUND

1. Field of the Invention

The invention relates generally to a solar energy collecting apparatus to provide electric power, heat, or electric power and heat, and more particularly to a parabolic trough solar collector for use in concentrating photovoltaic systems.

2. Description of the Related Art

Alternate sources of energy are needed to satisfy ever increasing world-wide energy demands. Solar energy resources are sufficient in many geographical regions to satisfy such demands, in part, by photoelectric converting solar flux into electric power, and by thermally converting solar flux into useful heat. Solar energy conversion systems include concentrating photovoltaic systems, where optical elements are used to focus sunlight onto one or more solar cells for photoelectric conversion, and/or into a thermal mass for heat collection.

In an exemplar concentrating photolelectric system, a system of lenses and/or reflectors constructed from less expensive materials can be used to focus sunlight on smaller and comparatively more expensive solar cells. The reflector may focus sunlight onto a surface in a linear or elongated strip pattern. By placing a strip of solar cells or a linear array of solar cells in the focal plane of such a reflector, the focused sunlight can be absorbed and converted directly into electricity by the cell or the array of cells. Concentration of sunlight by optical means can reduce the required surface area of photovoltaic material needed per watt of electricity generated, while enhancing solar-energy conversion efficiency, as more electrical energy can be generated from such a concentrator than from a flat plate solar cell with the same surface area. There is a need to improve the performance, efficiency, and reliability of concentrating photovoltaic systems, while improvements in the cost of manufacturing, ease of installation and the durability of such systems are also needed.

### SUMMARY

Systems, methods, and apparatus by which solar energy may be collected to provide electricity, heat, or a combination of electricity and heat are disclosed herein.

A solar energy collector includes one or more rows of solar energy reflectors and receivers, wherein individual continuous field areas of reflective media in a reflector section of a reflector of the reflectors in the collector are positioned side-by-side to form an arc of individual continuous field areas of reflective media in a reflector section of a reflector. Each row of reflectors comprises one or more reflectors positioned side by side along a line so that the foci from their reflective media are collinear, and one or more receivers arranged in line and fixed in position with respect to the reflectors with each receiver located approximately at the focus line of a corresponding reflector A support structure pivotably supports the reflectors and the receivers of the one or more such rows to accommodate rotation of the reflectors and the receivers about a rotation axis parallel to the focus line to which rays of light reflected from the reflective media formed in an arc shape substantially uniform for all reflectors in that row. In use, the reflectors and receivers are rotated about rotation axes on a rotation shaft to track the sun such that solar radiation or light rays falling on the surface of the reflective media of the reflectors is reflected and thereby directed and concentrated onto the receivers and across receiver surfaces.

In one embodiment, a solar energy collector includes a receiver, a first reflector and a second reflector arranged end-to-end such that an edge of the first reflector overlaps an edge of the second reflector. The overlapping of the edges of the reflectors minimizes a shadow effect often experienced by such installations. The shadow effect occurs when light rays are directed at a gap between the reflectors do not reflect from the gap and thus an absence of a reflection will show up a diminished reflection or a shadow (shadow effect) on the receiver, thereby inhibiting (or reducing) the amount of light reflected from the reflector to the receiver. The solar energy collector also includes a support structure that accommodates movement of the receiver, rotation of the reflectors, or rotation of the receiver and the reflectors about a rotation axis parallel to a long axis of the receiver. The support structure includes one or more reflector supports oriented transverse to the rotation axis and the reflectors are securable to the reflector supports.

The reflector arrangement allows a simple fabrication process, using thinner materials, with the reflectors positioned side-by-side along the long axis of the receiver with their ends overlapped to eliminate any shadowing effect that might be created by gaps between reflectors placed end-to-end within the structure of the solar collector. Additionally, flat sections of reflective media are used rather than preset curved reflective media (mirrors) to provide production and installation handling benefits not previously achieved.

These and other features and advantages of the embodiments described will become more apparent to those skilled in the art when taken with reference to the following more detailed description.

### BRIEF DESCRIPTION OF THE DRAWINGS

A more particular description may be had by reference to embodiments, some of which are illustrated in the appended drawings. It is to be noted, however, that the appended drawings illustrate only typical embodiments and are therefore not to be considered limiting in scope.

FIGS. 1A-1C show front (FIG. 1A), rear (FIG. 1B) and side (FIG. 1C) views of an example solar energy collector.

FIG. 2A shows, exploded illustration of details of a transverse reflector support mounted to a rotation shaft and mounting locations for reflectors including reflectors pre-final assembly as they are assembled to a mounted position on the transverse reflector support.

FIG. 2B shows, in a perspective view, a partial end view of the underside of a reflector.

FIG. 2C shows a cross-sectional schematic view of the end-to-end arrangement of reflectors attached to a transverse reflector support.

FIGS. 3A-3C show front side views of a reflector.

FIGS. 4A-4B schematically illustrate examples of the geometries of several different reflective element end-to-end arrangements at gaps between adjacent reflective elements.

FIG. 4C illustrates an example geometry of one reflective element end-to-end arrangement at a gap between adjacent reflective elements arranged to overlap another.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the description as understood by persons skilled in the art. The detailed description illustrates by way of example several embodiments, adaptations, variations, alternatives and uses of the structures and methods described.

As used in this specification and the appended claims, the singular forms “a,” “an,” and “the” include plural referents unless the context clearly indicates otherwise, Also, the term “parallel” is intended to mean “parallel or substantially parallel” and to encompass minor deviations from parallel geometries rather than to require that any parallel arrangements described herein be exactly parallel. Similarly, the term “perpendicular” is intended to mean “perpendicular or substantially perpendicular” and to encompass minor deviations from perpendicular geometries rather than to require that any perpendicular arrangements described herein be exactly perpendicular.

This specification discloses apparatus, systems, and methods by which solar energy may be collected and directed to a target to provide electricity, heat, or a combination of electricity and heat.

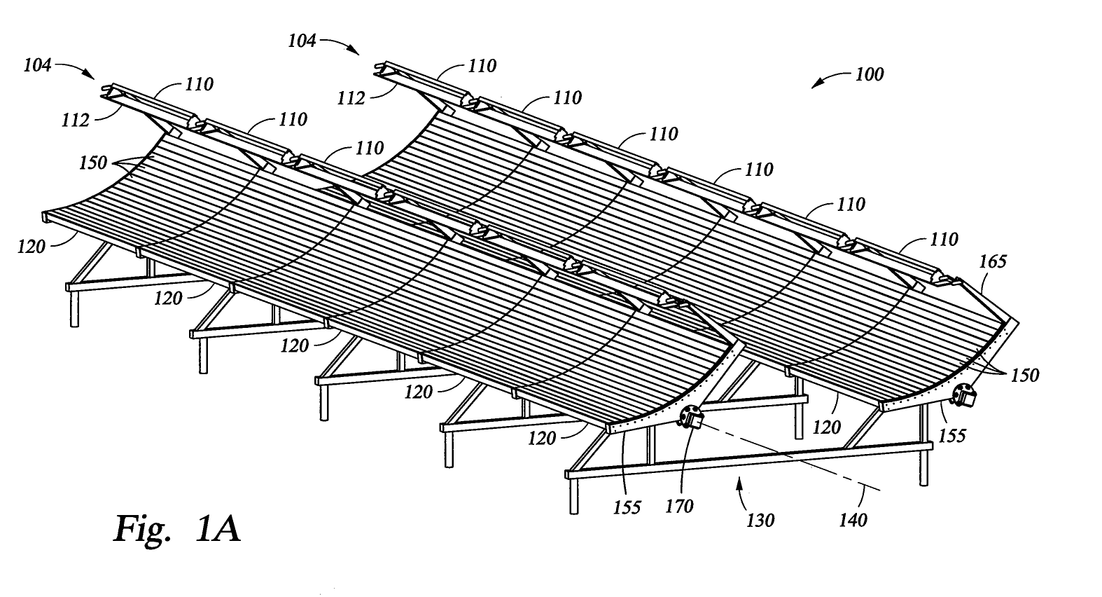

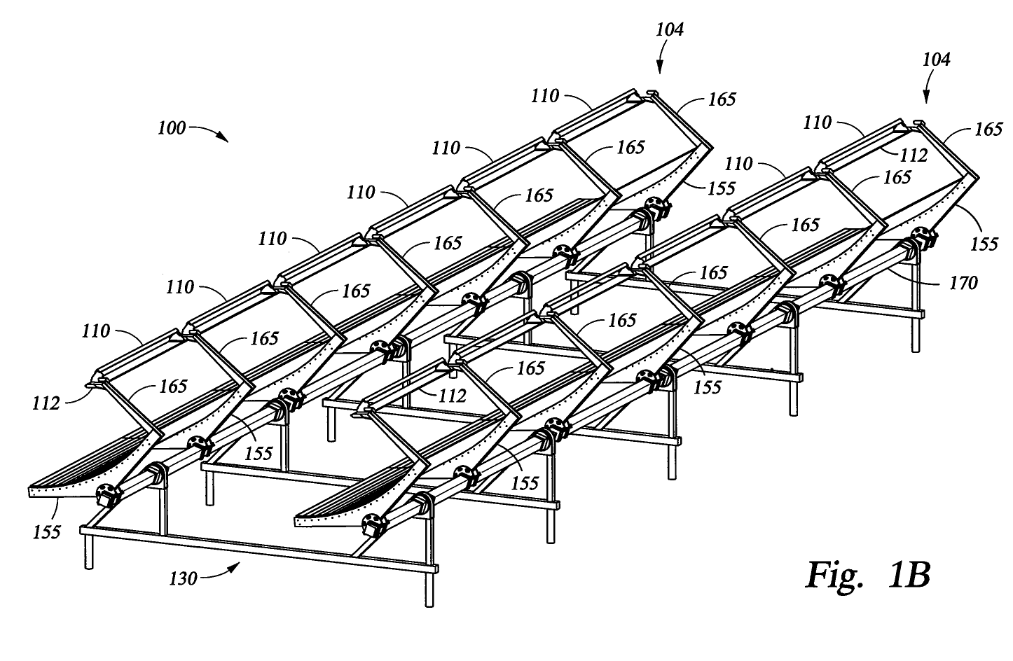

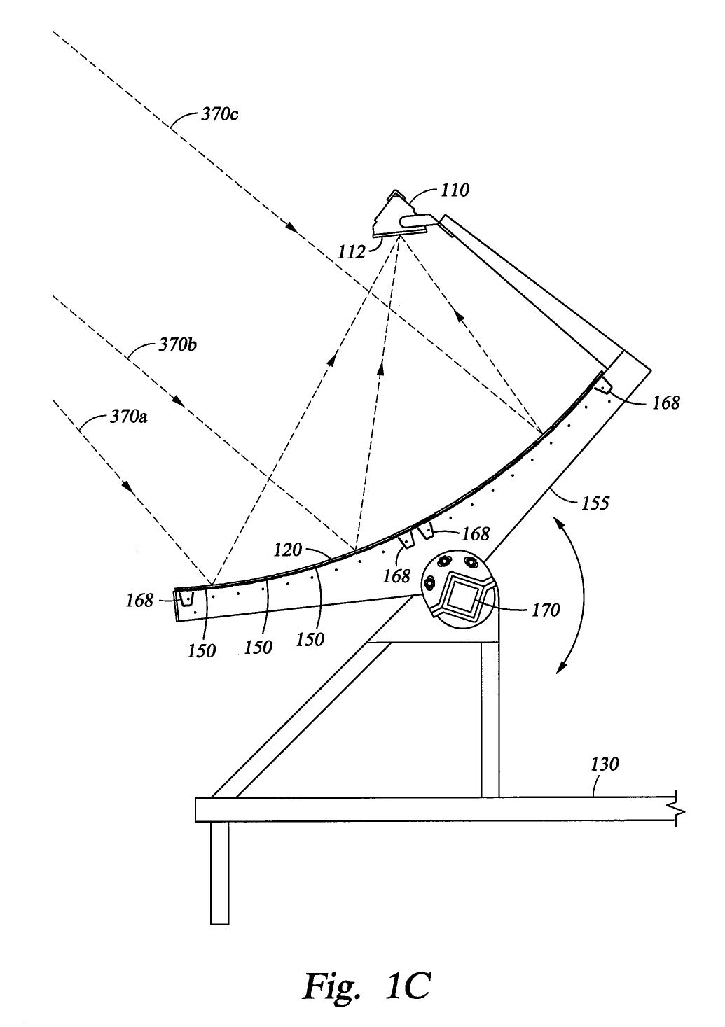

Referring now to FIGS. 1A, 1B and 1C, an example solar energy collector 100 comprises one or more rows 104 of modules of solar energy reflectors and receivers. Each such row 104 comprises one or more modules. Each module includes one or more reflectors 120 linearly aligned and configured in an arc or parabolic profile shape, and a receiver 110 is arranged in line and fixed in position with respect to the reflector(s) 120, with each receiver 110 comprising a light receiving surface 112 (FIGS. 1A, 1C and 1B) located at or approximately at a focal line of the light reflected from the reflecting surface of the corresponding reflector(s) (e.g., 120). As illustrated in FIG. 1C, a support structure 130 pivotably supports the reflectors 120 and the receivers 110 to accommodate rotation of the reflectors 120 and the receivers 110 about a rotation axis 140 to enable the reflectors, to be pointed at, and track the movement of, the sun. In use, as illustrated in FIG. 1C, the reflectors 120 and receivers 110 are rotated about rotation axes (e.g., 140) (best shown in FIG. 1A) on rotation shaft 170 to track the sun such that solar radiation (e.g., light rays 370a, 370b and 370c) falling on the reflective surface of reflectors 120 is concentrated onto and across the surface of receivers 110, (i.e., such that the centerline of the parabolic axis of the reflectors 120 is directed at the sun, when a parabolically shaped reflective surface profile is used).

In other variations, a solar energy collector otherwise substantially identical to that of FIGS. 1A and 1B may comprise only a single row 104 of the modules comprised of reflectors 120 and receivers 110, with support structure 130 modified accordingly.

As is apparent from FIGS. 1A and 1B solar energy collector 100 may be viewed as having a modular structure with reflectors 120 and receivers 110 having approximately the same length, and each pairing of a reflector 120 with a receiver 110 being an individual module. Rows 104 of solar energy collector 100 may thus be scaled in size by adding or removing such interconnected modules at the ends of solar energy collector 100, with the configuration and dimensions of support structure 130 adjusted accordingly.

Although each reflective surface of the reflector 120 has a parabolic or approximately parabolic profile in the illustrated example, the reflective surface of reflectors 120 need not have a parabolic or approximately parabolic reflective surface. In other variations, reflectors 120 may have reflective surfaces having any curvature suitable for concentrating solar radiation onto a receiver.

In the example of FIGS. 1A, 1B and 1C, each reflector 120 comprises a plurality of linear reflective elements 150 (e.g., mirrors) linearly aligned and extended and oriented about, and aligned to reflect sunlight to, a linear focus (line) of the reflective surface of the reflector 120 and fixed in position with respect to each other and with respect to its corresponding receiver 110. As shown, linear reflective elements 150 having a reflective surface each have a length equal or approximately equal to that of reflector 120 and are arranged side-by-side across the width of the reflector to form the reflective surface of reflector 120. In other variations, however, some or all of linear reflective elements 150 may be shorter than the length of reflector 120, in which case two or more reflective elements 150 may be arranged end-to-end to form a row of reflective elements 150 along the length of reflector 120. Additionally, two or more such rows may be arranged side-by-side to form a reflective surface for use with a reflector 120. Typically, the lengths of linear reflective elements 150 are much greater than their widths. Hence, linear reflective elements 150 typically have the form of reflective slats. In some variations, the linear reflective elements 150 may be longer than the length of reflector 120.

In the illustrated example, linear reflective elements 150 each have a width of about 75 millimeters (mm) and a length of about 2440 mm. In other variations, linear reflective elements 150 may have, for example, widths of about 20 mm to about 400 mm and lengths of about 1000 mm to about 4000 mm. Linear reflective elements 150 may be flat or substantially flat, as illustrated, or alternatively may be curved along a direction transverse to their long axes to individually direct incident solar radiation on the corresponding receiver. Although FIG. 1C shows light rays 370a, 370b and 370c all converging on at a single point on surface 112 of receiver 110, the figures are for illustrative only and should not be understood to be limiting. One skilled in the art would understand that the reflective surfaces of linear reflective elements 150 together direct the incident solar radiation to focus generally uniformly across the flat light receiving surface 112 of receiver 110. By providing the reflective elements having a width approximately equal to, or wider than, the corresponding light receiving surface of the receivers, each linear reflective element 150 will reflect light so that it is directed over the entire width of the light receiving surface of the receiver resulting in an equal dispersion of the incident solar radiation across receiver 110 providing a more efficient use of a solar cell positioned thereon.

Although in the illustrated example each reflector 120 comprises linear reflective elements 150, in other variations a reflector (e.g., 120) may be formed from a single continuous reflective element, from two reflective elements, or in any other suitable manner.

Linear reflective elements 150, or other reflective elements used to form a reflector 120, may be or comprise, for example, any suitable front surface mirror or rear (back) surface mirror. The reflective properties of the mirror may result, for example, from any suitable metallic or dielectric coating or polished metal surface. In other variations, reflective elements 150 may be any suitable reflective material.

In variations in which reflectors 120 comprise linear reflective elements 150 (as illustrated), solar energy collector 100 may be scaled in size and concentrating power by adding or removing rows of linear reflective elements 150 to or from reflectors to make reflectors (e.g., 120) wider or narrower. In another embodiment, two or more reflectors 120 with an appropriate number of linear reflective elements 150 may be placed side-by-side across the width of support structure 130 transverse to the optical axis of reflectors 120, and the width and length of transverse reflector supports 155 (discussed below), may be adjusted accordingly.

Referring again to FIGS. 1A, 1B and 1C, each receiver 110 may comprise solar cells (not shown) located, for example, on receiver surface 112 (best shown in FIG. 1C) to be illuminated by solar radiation concentrated by a corresponding reflector 120. In other variations, each receiver 110 may further comprise one or more coolant channels accommodating flow of liquid coolant in thermal contact with the solar cells. For example, liquid coolant (e,g., water, ethylene glycol, or a mixture of the two) may be introduced into and removed from a receiver 110 through manifolds (not shown) at either end of the receiver located, for example, on a rear surface of the receiver shaded from concentrated radiation. Coolant introduced at one end of the receiver may pass, for example, through one or more coolant channels (not shown) to the other end of the receiver from which the coolant may be withdrawn. This may allow the receiver to produce electricity more efficiently (by cooling the solar cells) and to capture heat (in the coolant). Both the electricity and the captured heat may be of commercial value.

In some variations, the receivers 110 comprise solar cells but lack channels through which a liquid coolant may be flowed. In other variations, the receivers 110 may comprise channels accommodating flow of a liquid to be heated by solar energy concentrated on the receiver, but lack solar cells. Solar energy collector 100 may comprise any suitable receiver 110. In addition to the examples illustrated herein, suitable receivers may include, for example, those disclosed in U.S. patent application Ser. No. 12/622,416, filed Nov. 19, 2009, titled “Receiver For Concentrating Photovoltaic-Thermal System;” and U.S. patent application Ser. No. 12/774,436, filed May 5, 2010, also titled “Receiver For Concentrating Photovoltaic-Thermal System;” both of which are incorporated herein by reference in their entirety.

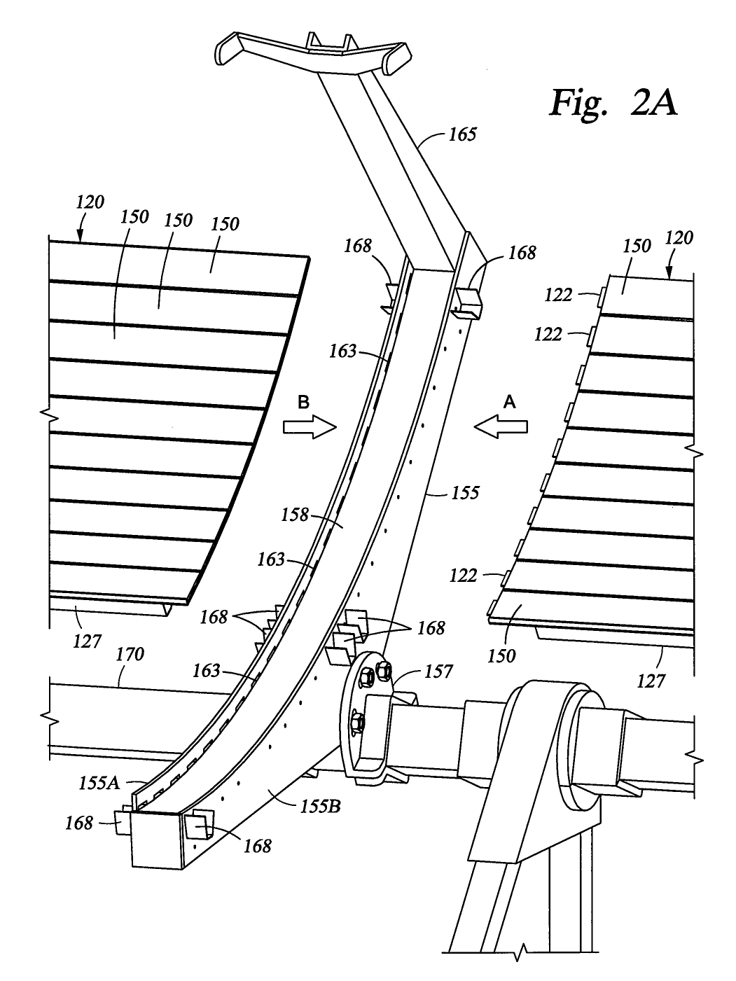

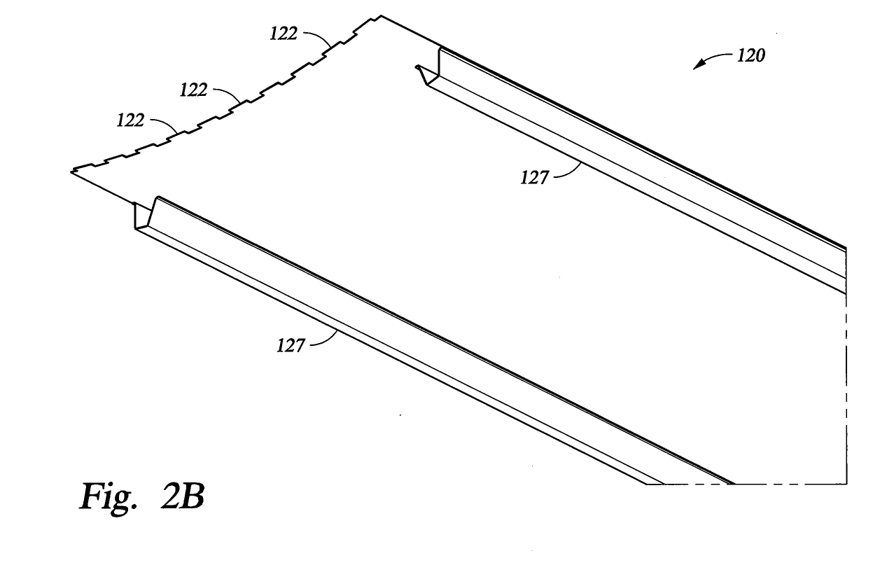

Referring again to FIGS. 1A, 1B and 1C as well as to FIG. 2A, in the illustrated example support structure 130 comprises a plurality of transverse reflector supports 155 and reflectors 120, which together support linear reflective elements 150. Each transverse reflector support 155 extends curvelinearly and transversely to the rotation axis 140 of the reflector 120 it supports. The reflector 120 supports a plurality of linear reflective elements 150 positioned side-by-side, or rows of linear reflective elements 150 arranged end-to-end, and extends parallel to the rotation axis of the reflector 120.

Support structure 130 also comprises a plurality of receiver supports 165 each connected to and extending from an end, or approximately an end, of a transverse reflector support 155 to support a receiver 110 over its corresponding reflector 120. As illustrated, each reflector 120 (described in detail below) is supported by two transverse reflector supports 155, with one transverse reflector support 155 at each end of the reflector 120. Similarly, each receiver 110 is supported by two receiver supports 165, with one receiver support 165 at each end of receiver 110 (FIGS. 1A and 1B). Other configurations using different numbers of transverse reflector supports per reflector and different numbers of receiver supports per receiver may be used, as suitable. The arrangement of receiver supports 165 and transverse reflector supports 155 is configured to enable the receivers 110 to be positioned at a focal plane of the reflective surface of the reflectors 120, to where the paths of light reflected from the reflected surface are narrowed (concentrated) to a dimension near the width dimension of the light receiving surface of the receiver.

In the illustrated example and referring to FIGS. 1C, 2A and 2C, each of the transverse reflector supports 155 comprises sidewalls 155A and 155B, bottom wall 155C and cross bar 158. Transverse reflector support 155 is attached to a rotation shaft 170 which provides for common rotation of the reflectors and receivers in that row about their rotation axis 140 (FIG. 1A), which is coincident with rotation shafts 170, (i.e., the reflectors and receivers are fixed relative to each other, but their angular orientation can change to cause the reflectors to maintain an optimal position with respect to the changing position of the sun). Rotation shafts 170 are pivotably supported by slew posts and bearing posts. In other variations, any other suitable rotation mechanism may be used.

In the example shown in FIG. 2A, transverse reflector support 155 is attached to rotation shaft 170 with a two-piece clamp 157. Clamp 157 has an upper half attached (for example, bolted) to transverse reflector support 155 and conformingly fitting an upper half of rotation shaft 170. Clamp 157 has a lower half that conformingly fits a lower half of rotation shaft 170. The upper and lower halves of clamp 157 are attached (for example, bolted) to each other and tightened around rotation shaft 170 to clamp transverse reflector support 155 to rotation shaft 170. Rotation shaft 170 is illustrated as a square shaped shaft, but in practice different shapes may be used including round or oval, or any other suitable linear support structure such as a truss. In some variations, the rotational orientation of transverse reflector support 155 may be adjusted with respect to the rotation shaft by, for example, about +1-5 degrees. This may be accomplished, for example, by attaching clamp 157 to transverse reflector support 155 with bolts that pass through slots in the upper half of clamp 157 to engage threaded holes in transverse reflector support 155, with the slots configured to allow rotational adjustment of transverse reflector support 155 prior to the bolts being fully tightened.

In the illustrated example in FIGS. 2A and 2B, the upper portion of the sidewalls 155A and 155B of the transverse reflector supports 155 have any curvature suitable (i.e., a parabola) for concentrating solar radiation reflected from the reflectors 120 mounted thereon to receiver 110. Additionally, sidewalls 155A and 155B of the transverse reflector support 155 can include integrated features to secure the reflector 120 to transverse reflector support 155. For example, slots 163 positioned at the upper edge of sidewall 155A are distributed from end-to-end over the transverse length of transverse reflector support 155 to enable tabs 122 at one edge of the longitudinal end of reflector 120 to slide into slots 163 to secure reflector 120 in position. Slots 163 are positioned in only one sidewall such as sidewall 155A of transverse reflector support 155, and the sidewall 155A containing slots 163 is taller than the opposing sidewall 155B of transverse reflector support 155. As best seen in FIG. 2C, the difference in heights between the two sidewalls is such that the taller sidewall 155A accommodates slots 163, but also accommodates the height of reflector 120, including the height of linearly extending reflector elements 150, as a reflector 120 sits on the shorter opposing sidewall 155B with tabs 122 engaged in slots 163 (in sidewall 155A) so as to allow the edge of a second reflector 120 to sit on the taller sidewall 155A such that the edge of reflector 120 positioned on the taller sidewall 155A will overlap the underlying reflector 120 without touching the first reflector 120 positioned below on the shorter opposing sidewall 155B.

Additional features that enable transverse reflector support 155 to secure reflector 120 include joist hangers 168 positioned on the outer sidewall 155A and 155B of the transverse reflector support 155 and placed so as to capture the ends of stretcher bars 127 as shown in FIGS. 2A, 2B and 2C. Stretcher bars 127 positioned lengthwise along each edge of reflector 120 provides strength and stability to reflector 120 and further support reflector 120 during periods of high wind or heavy snow. The ends of stretcher bar 127 may be secured to joist hangers 168 by any mechanical means including bolts and rivets (not shown).

As illustrated by arrow A in FIG. 2A, the edge of reflector 120 that includes tabs 122 is placed on the nearest sidewall 155B and slid into place in the direction of arrow A to enable the tabs 122 to slip into slots 163 in the opposite sidewall 155A thus securing the reflector 120 into position on transverse reflector support 155. The arrow B illustrates the direction the second reflector 120 is moved to be positioned on the taller sidewall 155A such that the edge of the second reflector overlaps the edge of the first reflector as shown in FIG. 2C. The edge of the second reflector is secured to transverse reflector support 155 by means of the ends of stretcher bars 127 placed in and mechanically connected (not shown) to joist hangers 168 (best shown in FIGS. 2A and 2C). Tabs 122 are positioned at only one longitudinal edge of reflector 120 as the opposing edge does not require the tabs 122 as only one edge is positioned to engage slots 163 while the opposing edge of each reflector 120 will overlay the reflector 120 positioned below. In some variations, clips or other connectors may be added between transverse reflector support 155 and the end of the reflector 120 that does not have tabs 122 to further secure the reflector 120 to transverse reflector support 155.

Typically, one sidewall of a single transverse reflector support 155 supports one end of a first reflector 120 and the opposing sidewall supports the adjacent end of another reflector 120 and the taller sidewall also includes slots 163 to engage tabs 122 of one of the reflector 120 so that when the two reflectors 120 are arranged linearly end-to-end such that there is an overlap of the edges. The transverse reflector support 155 that supports the edge of reflector 120 positioned at each end of the collector 100 may be adjusted to have each sidewall of equal height (not shown).

In the illustrated example, the curved upper sidewall 155A and 155B surfaces of transverse reflector support 155 provide reference surfaces that orient reflectors 120, and thus the linear reflective elements 150 they support, in a desired orientation with respect to a corresponding receiver 110 with a precision of: for example, about 0.5 degrees or better (i,e., tolerance less than about 0.5 degrees). In other variations, this tolerance may be, for example, greater than about 0.5 degrees.

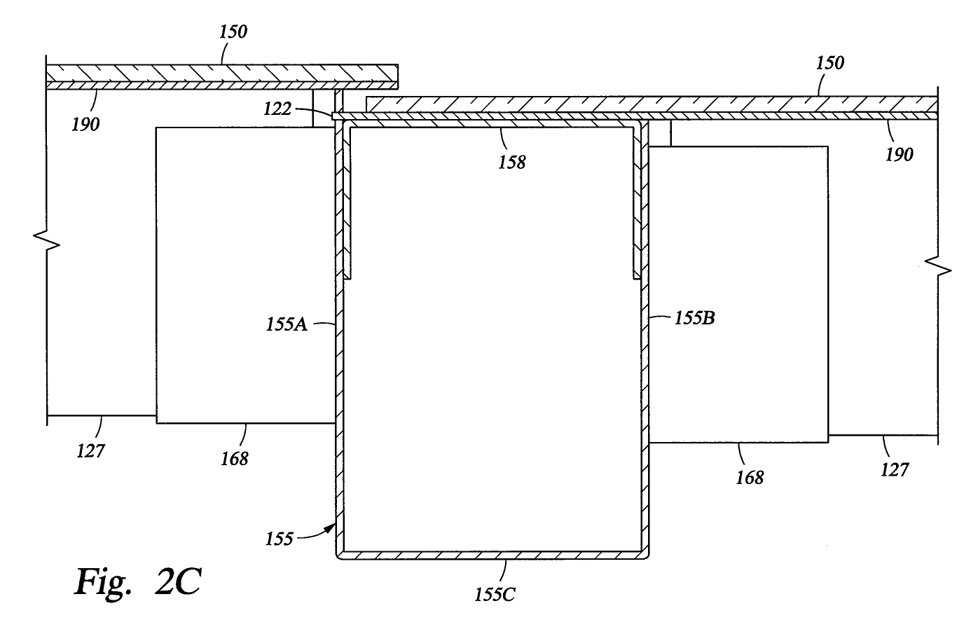

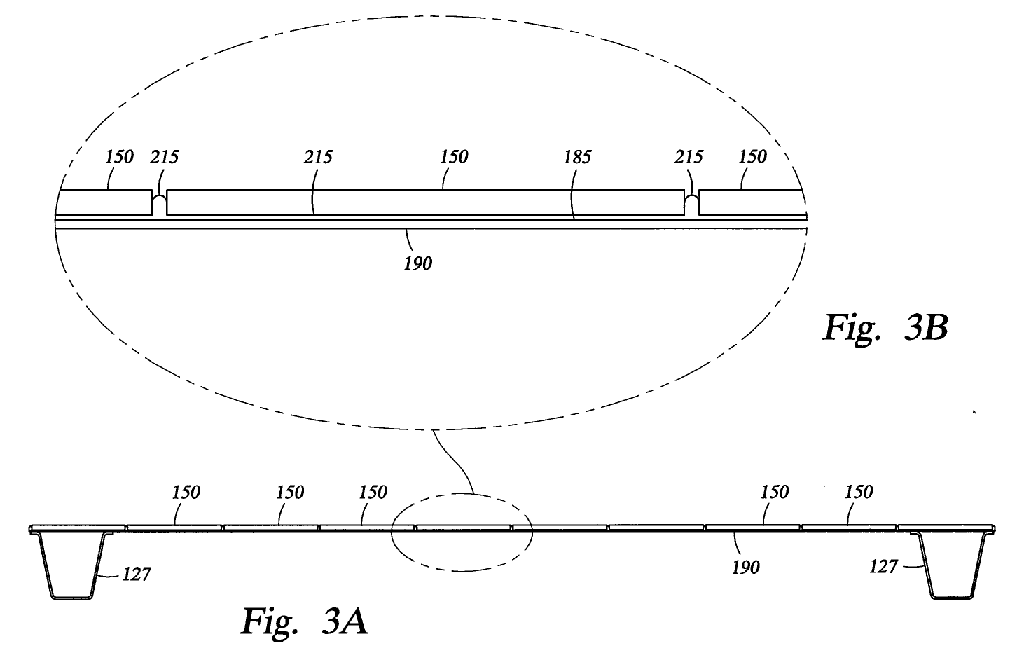

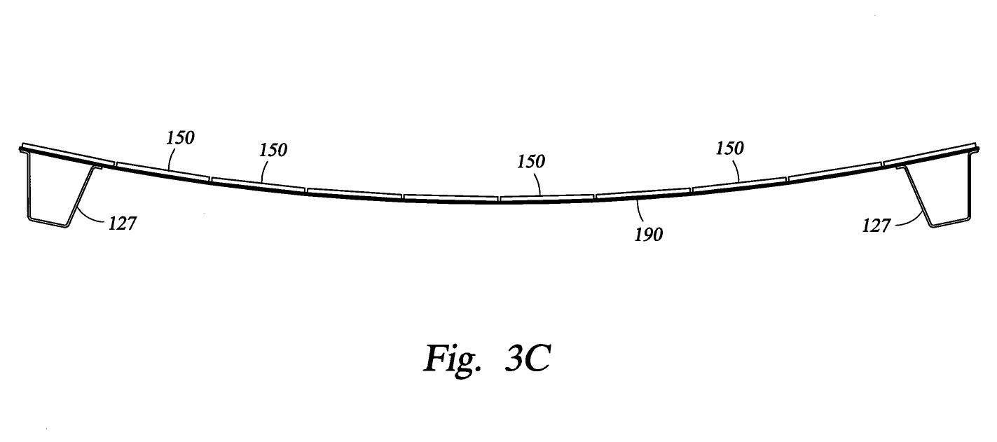

FIGS. 3A, 3B and 3C show cross-sectional side views of an example reflector 120 viewed perpendicularly to its long axis. In the illustrated example, reflector 120 has a reflector tray 190 comprising an upper tray surface 185, stretcher bars 127 which serve as longitudinal support frames. Linear reflective elements 150 are positioned side-by-side on the upper tray surface 185 of reflector tray 190. The linear reflective elements 150 are positioned side-by-side such that a small gap extends the length of reflector 120 between each of the linear reflective elements 150 (as shown in FIG. 1).

In the illustrated example, reflector tray 190 is about 2440 mm long and about 600 mm wide (sized to accommodate 8 linear reflective elements). In other variations, reflector tray 190 is about 1000 mm to about 4000 mm long and about 300 mm to about 800 mm wide.

Referring to FIG. 3B, each linear reflective element 150 is held in place on the upper tray surface 185 with glue or other adhesive 215. The adhesive 215 coats the entire upper tray surface 185 and thus coats the complete underside of the linear reflective elements 150. In some variations, adhesive 215 may only coat portions of the underside of reflective elements 150. In other variations, a filler material such as silicon sealant or other bonding agent may be used to fill gaps and provide a seal between reflective elements 150. Any other suitable method of attaching the linear reflective element 150 to the reflector tray 190 may be used, including adhesive tape, screws, bolts, rivets, clamps, springs and other similar mechanical fasteners, or any combination thereof.

In addition to attaching linear reflective elements 150 to upper tray surface 185, in the illustrated example adhesive 215 positioned between the outer edges of the rows of linear reflective elements 150 and covering the outer edges of the outermost linear reflective element 150 may also seal the edges of the linear reflective elements 150 and thereby prevent corrosion of linear reflective elements 150. This may reduce any need for a sealant separately applied to the edges of the linear reflective elements 150. Adhesive 215 positioned between the bottom of the linear reflective element 150 and upper tray surface 185 may mechanically strengthen the linear reflective element 150 and also maintain the position of linear reflective elements 150 should they crack or break. Further, reflector tray 190 together with adhesive 215 may provide sufficient protection to the rear surface of the linear reflective element 150 to reduce any need for a separate protective coating on that rear surface to protect reflective element 150 from scratching, chemicals and environmental conditions such as dust, dirt and water.

The reflector tray 190 to which the linear reflective elements 150 are adhered is made of sheet metal or other similar material with elastic properties and a thickness that allows the reflector tray 190 to flex and bend into a position matching the curvature of the transverse reflector support 155 forming a parabolic shape or similarly suited curved shape. The reflector tray 190 will bend between the mirrors as the stiffness of the combination of the metal of the reflector tray 190 and the reflective elements 150 is greater than the stiffness of the metal of the reflector tray 190 alone. The flexible properties of reflector tray 190 allows the reflector 120 to be manufactured by adhering (fixing) the linear reflective elements 150 to a flat surface that can be easily shipped and subsequently bent or allowed to flex or bend into its final shape in the field during the assembly of collector 100. In addition, the flexible nature of the reflector 120 materials will help prevent warping of reflector 120 (and breaking of linear reflective elements 150) if materials with a different coefficient of thermal expansion are used for transverse reflector support 155 than the materials used for reflector tray 190.

Referring back to FIG. 1A, reflectors 120, comprising linear reflective elements 150, are arranged linearly end-to-end across the length of the collector 100. Typically, gaps are created between the ends of linear reflective elements for each of the reflectors. These gaps between reflectors in the solar energy collector 100 may cause shadows that produce non-uniform illumination of the receiver and have a negative effect on the efficiency of the receiver and significantly reduce the power output of collector 100.

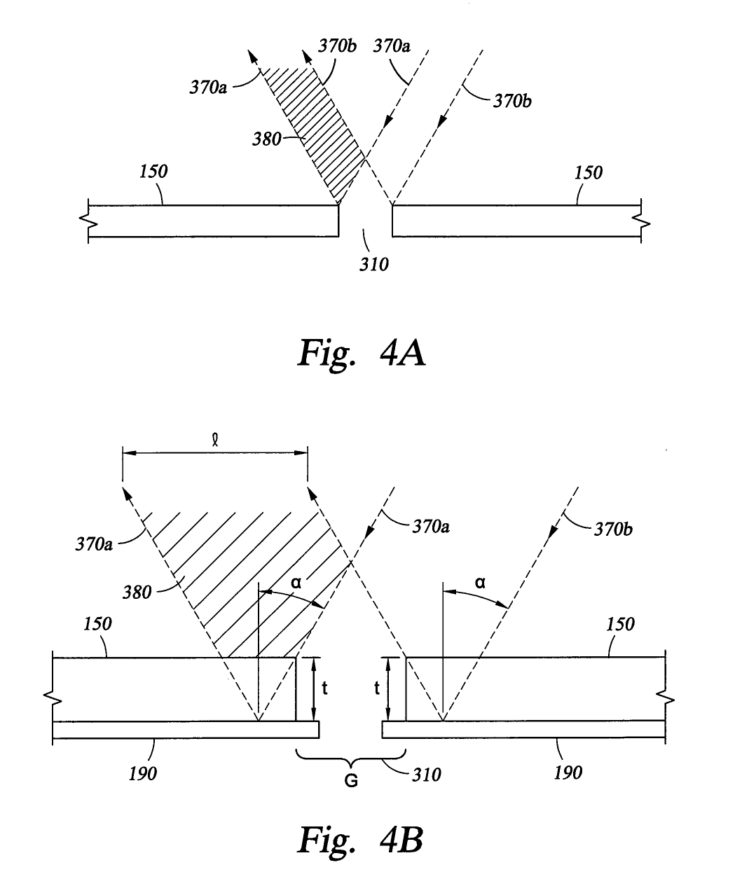

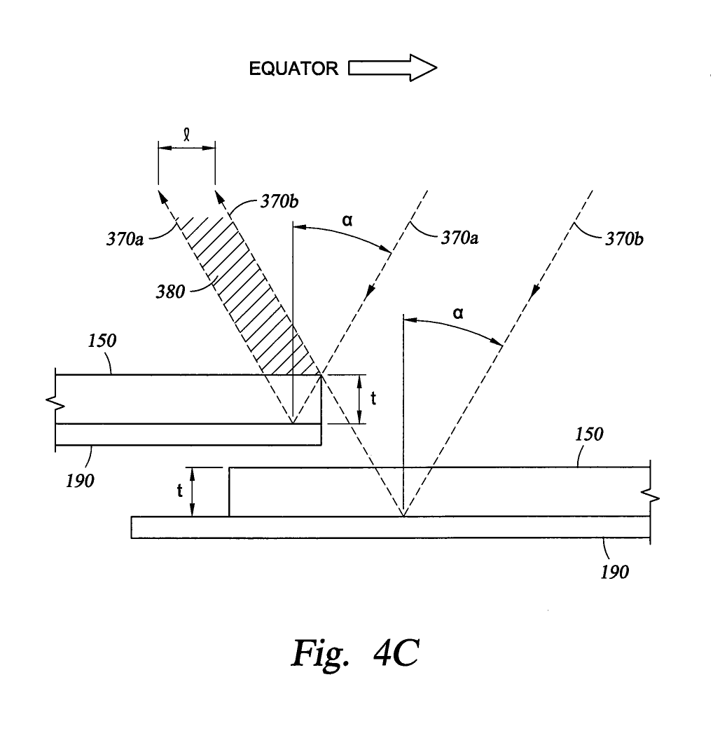

Referring to FIG. 4A, for example, shows light rays 370a, 370b incident on ends of linear reflective elements 150 adjacent to gap 310 are reflected in parallel and hence cast a shadow 380 because no light is reflected from the gap 310. In some embodiments, (FIG. 4B) where glass mirrors are used as the linear reflected elements 150, the light rays 370a and 370b go through the glass portion of the mirror to the reflective surface below and are reflected back through the glass directed at the receiver 110. For those light rays 370a and 370b that enter the top portion of the glass near the edge portions of the glass at gap 310 would otherwise be reflected towards the reflector 120, but due to the proximity of the light rays to the side edge of the glass are actually directed through the side edge of the glass along gap 310. These light rays scatter as they exit the side edge of the glass thereby further widening shadow 380 as shown by the application of equation 2t(tan α)+G=l to the structures shown in FIG. 4B. In this example, “t” is the thickness of the glass, “α” is the angle of the light rays 370a and 370b, “G” is the width of the gap between reflective elements and “l” is the total length of shadow. The length of shadow “l” will never be less than the size of the gap “G”. As angle “α” of light rays 370a and 370b approaches 0, the length “l” of shadow 380 approaches 0. Thus at solar noon, there is no shadow and at other times of the day, the shadow 380 will vary by a tangent trigonometric function. The variation is present when the sun (light rays 370a and 370b) is not near solar noon.

Referring to FIGS. 2C and 4C, for example, ends of reflective elements 150 are stacked and overlap each other to eliminate the gap 310 (FIGS. 5A and 5B) caused by placing the reflective elements 150 end-to-end. Because the sun moves around the earth's equator, the top stacked reflector 120 is always positioned away from the earth's equator relative to the underlying reflector 120. With the reflectors 120 stacked, and the top stacked reflective elements 150 positioned away from the earth's equator relative to the underlying reflective elements 150, the gap is removed such that the length “l” of the shadow 380 is solely dependent on the thickness “t” of the mirror of reflective elements 150 and the angle “α” of light rays 370a and 370b as shown in the equation 2t(tan α)=l. For example, when the light rays are vertical to the reflector 120, no shadow exists as the reflective elements 150 overlap removing any gap as shown in between e. As the sun and associated light rays move to a larger angle from center, the resulting shadow is spread along different points of the receiver so much so that the effects of the shadow no longer impacts the performance of the receiver. Note that if the reflective elements 150 are not stacked and oriented with the top reflective elements 150 positioned away from the earth's equator as described above, the length of the shadow “l” would be much greater. In this instance, if the light rays 370a and 370b were directed at reflective elements 150 in the opposite direction as is currently shown in FIG. 4C, the length “l” of the shadow would need to include the depth of the lower reflective element 150 from the upper reflective element 150. Any increase in the length of the shadow would contribute to the non-uniformity of the light rays directed to illuminate the receiver 110 and decrease the efficiency of the solar collector 100.

This disclosure is illustrative and not limiting. Further modifications will be apparent to one skilled in the art in light of this disclosure and are intended to fall within the scope of the appended claims. All publications and patent application cited in the specification are incorporated herein by reference in their entirety.

While the foregoing is directed to embodiments according to the present invention, other and further embodiments may be devised without departing from the basic scope thereof, and the scope thereof is determined by the claims that follow.

1. A solar energy collector comprising:
a linearly extending receiver comprising solar cells;
at least a first trough reflector having a first end and a second trough reflector having a first end arranged end-to-end with the first end of the first trough reflector adjacent to the first end of the second trough reflector to linearly extend parallel to a long axis of the receiver, the first trough reflector and the second trough reflector fixed in position with respect to the receiver with their linear foci in line and oriented parallel to the long axis of the receiver and located at or approximately at the receiver; and
a support structure that accommodates rotation of the receiver and the reflectors about a rotation axis parallel to the long axis of the receiver;
wherein the support structure comprises a reflector support extending transversely to the rotation axis beneath the first end of the first trough reflector and the first end of the second trough reflector and attached to and supporting the first end of the first trough reflector and the first end of the second trough reflector at different distances from the receiver.

2-29. (canceled)

30. The solar energy collector of claim 1, wherein the first end of the first trough reflector and the first end of the second trough reflector overlap.

31. The solar energy collector of claim 1, wherein the transverse reflector support imposes a parabolic or approximately parabolic curvature on the first trough reflector and the second trough reflector.

32. The solar energy collector of claim 1, wherein:
the first trough reflector has a second end opposite from its first end and the second trough reflector has a second end opposite from its first end;
the first end of the first trough reflector is closer to the receiver than is the first end of the second trough reflector; and
the solar energy collector is installed at a site for operation with the first trough reflector positioned with its first end closer to the equator than is its second end and with the second trough reflector positioned with its first end further from the equator than is its second end.

33. The solar energy collector of claim 32, wherein the first end of the first trough reflector and the first end of the second trough reflector overlap.

34. The solar energy collector of claim 1, wherein the receiver comprises coolant channels accommodating flow of liquid coolant through the receiver.

35. The solar energy collector of claim 1, wherein each trough reflector comprises a plurality of linearly extending reflective elements oriented with their long axes parallel to the long axis of the receiver and arranged side-by-side in a direction transverse to the long axis of the receiver on a flexible tray.

36. The solar energy collector of claim 35, wherein the first end of the first trough reflector and the first end of the second trough reflector overlap.

37. The solar energy collector of claim 35, wherein the transverse reflector support imposes a parabolic or approximately parabolic curvature on the flexible trays.

38. The solar energy collector of claim 35, wherein:
the first trough reflector has a second end opposite from its first end and the second trough reflector has a second end opposite from its first end;
the first end of the first trough reflector is closer to the receiver than is the first end of the second trough reflector; and
the solar energy collector is installed at a site for operation with the first trough reflector positioned with its first end closer to the equator than is its second end and with the second trough reflector positioned with its first end further from the equator than is its second end.

39. The solar energy collector of claim 35, wherein the linearly extending reflective elements are attached to the trays with an adhesive.

40. The solar energy collector of claim 1, wherein:
the first end of the first trough reflector and the first end of the second trough reflector overlap;
each trough reflector comprises a plurality of linearly extending reflective elements oriented with their long axes parallel to the long axis of the receiver and arranged side-by-side in a direction transverse to the long axis of the receiver on a flexible tray;
the transverse reflector support imposes a parabolic or approximately parabolic curvature on the flexible trays; and
the receiver comprises coolant channels accommodating flow of liquid coolant through the receiver.

41. The solar energy collector of claim 40, wherein:
the first trough reflector has a second end opposite from its first end and the second trough reflector has a second end opposite from its first end;
the first end of the first trough reflector is closer to the receiver than is the first end of the second trough reflector; and
the solar energy collector is installed at a site for operation with the first trough reflector positioned with its first end closer to the equator than is its second end and with the second trough reflector positioned with its first end further from the equator than is its second end.
